(19) United States
(12) Patent Application Publication
(10) Pub. No.: US 2025/0172611 A1
(43) Pub. Date: May 29, 2025

(54) PREDICTIVE AND ADAPTIVE INFIELD TESTING BASED ON SILICON HEALTH INFORMATION

(71) Applicant: Intel Corporation, Santa Clara, CA (US)

(72) Inventors: Rakesh Kandula, Bangalore (IN); Fei Su, Ann Arbor, MI (US)

(21) Appl. No.: 18/520,740

(22) Filed: Nov. 28, 2023

(51) Int. Cl. G01R 31/3187; G01R 31/28; G01R 31/3193

(52) U.S. Cl. CPC G01R 31/3187; G01R 31/2896; G01R 31/3193

(57) ABSTRACT

In one embodiment, an apparatus includes: a functional circuit to execute operations; test circuitry to execute infield testing of at least a portion of the functional circuit; a plurality of sensors to sense sensor information; and a test controller coupled to the test circuitry, the test controller to prevent at least a portion of the test circuitry from execution of the infield testing based at least in part on the sensor information. Other embodiments are described and claimed.

### BACKGROUND

Typical integrated circuits (ICs) include test circuitry to perform infield testing to confirm compliance with operating requirements. One common test is infield scan testing that mainly includes scan stuck-at testing, at-speed testing, cell aware testing, and array built-in self-test (BIST) testing. These tests are executed on system on chip (SoC) silicon to screen any defective parts that are introduced during manufacturing and in the field.

These tests typically include two phases: a shift (in and out) phase and a capture phase. During the shift-in phase, a test pattern is serially loaded into a scan chain of the IC, and during the capture phase the shifted pattern is applied to functional logic of the IC and is captured. The captured response is shifted during the shift-out phase. The toggling rate of wires, especially during the capture phase is very high as compared to the toggling rate during functional scenarios and during the shift phase. This is so, since the scan tests target almost every wire to toggle (as high as >99.5%); hence it toggles most of the combinational logic. The power dissipated during the capture phase of scan tests can be very high and can cause a voltage droop, and the power leakage can be significantly high. Also, a rise in temperature during the capture phase can be catastrophic on an IC that is considerably aged. Thus existing infield testing can actually cause certain ICs to fail.

### BRIEF DESCRIPTION OF THE DRAWINGS

FIG. 1 is a flow diagram of a method in accordance with an embodiment.

FIG. 2 is a block diagram of a test arrangement in accordance with an embodiment.

FIG. 3A is a block diagram of an interface in accordance with an embodiment.

FIG. 3B is a block diagram of an interface in accordance with another embodiment.

FIG. 4 is a block diagram of a test arrangement in accordance with another embodiment.

FIG. 5 illustrates an example computing system.

FIG. 6 illustrates a block diagram of an example processor in accordance with an embodiment.

FIG. 7 is a block diagram of a processor core in accordance with an embodiment.

### DETAILED DESCRIPTION

In various embodiments, techniques are provided to enable an integrated circuit to deterministically execute infield scan testing. Such deterministic operation means that the infield tests are either performed periodically or prevented from being performed based at least in part on silicon health. In other cases, this deterministic operation may adaptively adjust a testing schedule, as will be described herein.

Information regarding the silicon health and the infield testing may be communicated to a user. Although embodiments are not limited in this regard, in some cases this information may identify critical parameters before and after infield testing is performed and/or an indication that infield testing has been halted based on the criticality of parameters in silicon.

Prior to executing an infield test, one or more parameters associated with silicon health may be monitored. As examples, these parameters (sometimes referred to herein as “critical parameters”) may include voltage and temperature levels, among others including information obtained from digital aging sensors, path margin monitors, and so forth.

Embodiments also provide information communication to a user. Such information enables the user to know about the health of the silicon in terms of critical parameters before and after infield tests are performed. In one embodiment, a user can be informed of the reason that an infield test is not performed (e.g., based on identification of one or more critical parameters that are not within a safe range). The user may also be informed of the reason for executing infield tests based on the parameters being in the safe range. Embodiments also let users know about an adverse event that occurred during the infield test execution. For example, such parameters can be communicated to the user at the end of infield test.

In some cases where critical parameters are not in a safe range (but not sufficiently far out of tolerance), infield testing may be performed, but in a degraded manner (e.g., reduction of testing time or testing patterns). A user may also be informed of this degraded testing operation, and the reasoning for it.

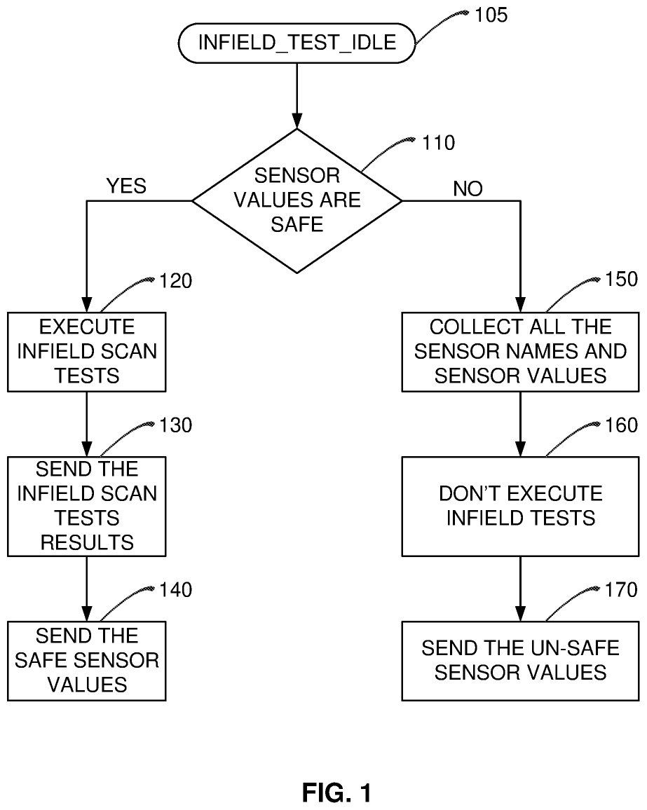

Referring now to FIG. 1, shown is a flow diagram of a method in accordance with an embodiment. As shown in FIG. 1, method 100 is a method for performing infield testing as described herein. As such, method 100 may be performed by hardware circuitry such as a test controller, alone or in combination with firmware and/or software.

As illustrated, method 100 occurs when infield testing is to begin from an idle condition (block 105). Next at diamond 110 it is determined whether relevant sensor values are in a safe range. This safe range refers to a set of sensor values for a given sensor that indicates that the measured parameter relating to silicon health is within acceptable tolerances. As examples, a safe range for a given sensor may be between lower and upper thresholds. Although embodiments are not limited in this regard, these sensors may be a variety of silicon health sensors that are adapted throughout a die.

If it is determined that the sensor values are safe, control passes to block 120 where infield scan tests may be executed. Then at block 130 the infield test results are sent to an end user. For example, test results may be stored in a storage, e.g., a given file, and the end user can view the infield test results. Similarly, at block 140 the safe sensor values themselves may be sent. As above, these values may be reported to the user via storage in a relevant file (that may be encrypted, in certain implementations).

Still with reference to FIG. 1, if instead it is determined at diamond 110 that at least one of the sensor values is not safe, control passes to block 150 where the sensor names and values are collected. In this situation where sensor values are not all safe, infield testing is not executed (block 160). Instead, the unsafe sensor values may be sent to the user (block 170), using the same mechanisms discussed above (e.g., storage in a file). Although shown at this high level in the embodiment of FIG. 1, variations and alternatives are possible. For example, instead of or in addition to scan testing, other infield testing may be performed according to method 100.

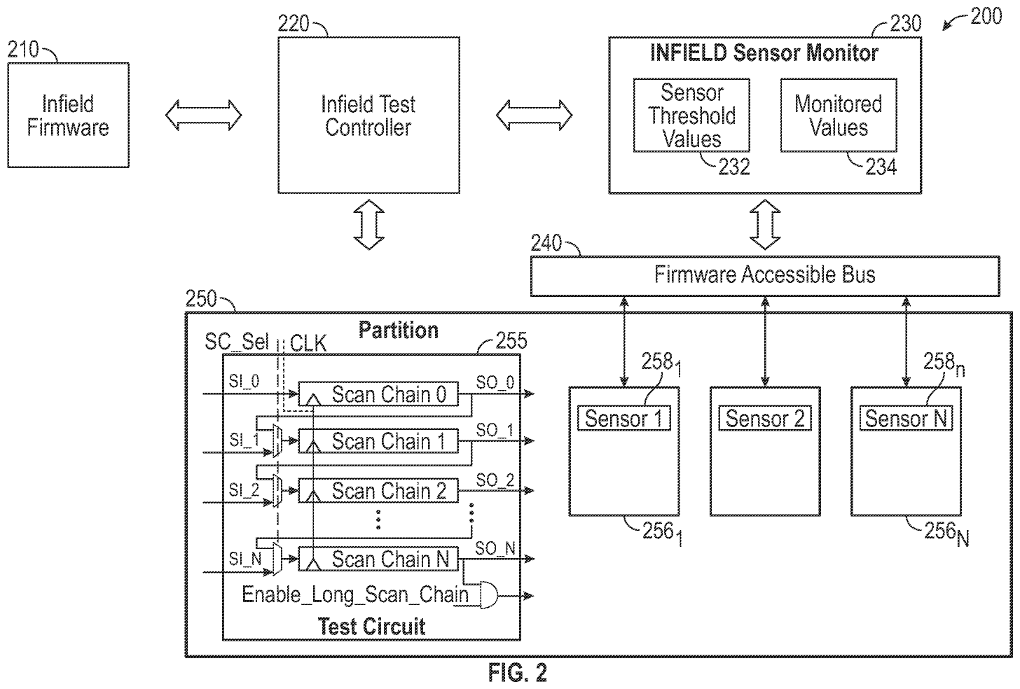

Referring now to FIG. 2, shown is block diagram of a test arrangement in accordance with an embodiment. As shown in FIG. 2, an integrated circuit 200 such as an SoC or other processor includes infield firmware 210 that couples to an infield test controller 220. In turn, field test controller 220 couples to an infield sensor monitor 230 and also couples to a partition 250. Understand that partition 250 may be a portion of a semiconductor die that includes test circuitry 255 which, in the embodiment shown, is implemented as scan chain circuitry along with associated sensors 2561-N. As seen, each sensor 256 includes a corresponding register 2581-N that is configured to store one or more sensor values. Sensors 256 may include temperature sensors, voltage droop monitors, intra-die variation sensors, digital aging sensors, and path margin monitors, among others.

As further shown in FIG. 2, infield sensor monitor 230 includes a set of sensor threshold values 232. These threshold values, which may be used to compare against received real-time sensor values, may be obtained from infield firmware 210 and stored within infield sensor monitor 230. When infield sensor monitor 230 receives measured values 234, it may compare a given corresponding sensor value to a corresponding sensor threshold to determine whether the relevant sensor information is within a safe range or an unsafe range. Note that in some embodiments, there may further be a delineation of a borderline region between a safe range and the unsafe range (or the borderline region may be a region of unsafe values close to the safe range, e.g., within 20% of the safe range; of course, understand that these values may vary depending upon the scenario or market segment).

In operation, infield firmware 210 can set an infield start bit inside infield test controller 220. In response, infield sense monitor 230 checks to determine whether all sensor values are within the safe range or not. If yes, then infield sense monitor 230 informs infield test controller 220 that the sensor values are in the safe range. In this case, infield test controller 220 proceeds to cause infield scan testing (e.g., via test circuit 255). If no, then infield sense monitor 230 informs infield test controller 220 that the sensor values are not in the safe range. If the sensor values are not in the safe range, infield test controller 220 does not cause the infield tests to start, and informs infield firmware 210. Infield firmware 210 informs the user about the sensor values followed by a message, e.g., “Infield tests are not executed.”

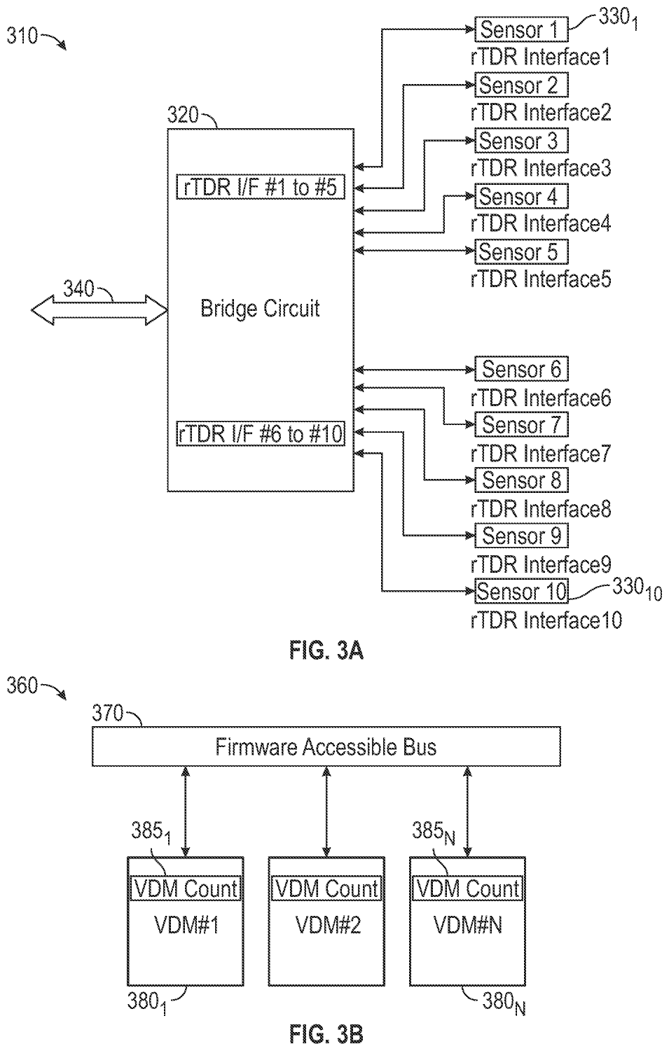

In the test arrangement, infield firmware 210 may read sensor values in different manners depending upon implementation. Referring now to FIG. 3A, shown is a block diagram of an interface in accordance with an embodiment. As shown in FIG. 3A, interface circuit 310 provides an implementation in which sensor values can be communicated to firmware via a bridge circuit 320 that provides for sensor circuitry to communicate using a Test Access Port (TAP) arrangement in accordance with a Joint Test Action Group (JTAG) protocol. In the embodiment of FIG. 3A, bridge circuit 320 is implemented as a firmware-to-TAP bridge that provides an interface with a plurality of sensors 330₁₋₁₀. In turn, bridge circuit 320 provides sensor values to firmware via a firmware interface 340, which in various embodiments can be implemented as an Advanced Peripheral Bus (APB) bus, Advanced Extensible Interface (AXI) bus, Advanced High-Performance (AHB) bus, Intel® On-Chip System Fabric (IOSF) sideband link, network on chip or so forth. Bridge circuit 320 may be implemented to convert a firmware bus protocol to a TAP protocol to read the values of the sensors having this TAP interface.

In another implementation, sensors may be directly accessible by firmware. Referring now to FIG. 3B, shown is a block diagram of an interface in accordance with another embodiment. As shown in FIG. 3B, interface circuit 360 provides an implementation in which sensor values can be directly communicated to firmware via a bus 370, implemented as a firmware accessible bus. In this arrangement, sensors 380_{1-N} include corresponding registers 385_{1-N}, which can store count or other sensor values that can be directly read by firmware as memory mapped input output (MMIO) registers. In an embodiment, sensors 380 can be implemented as voltage droop monitors (VDMs).

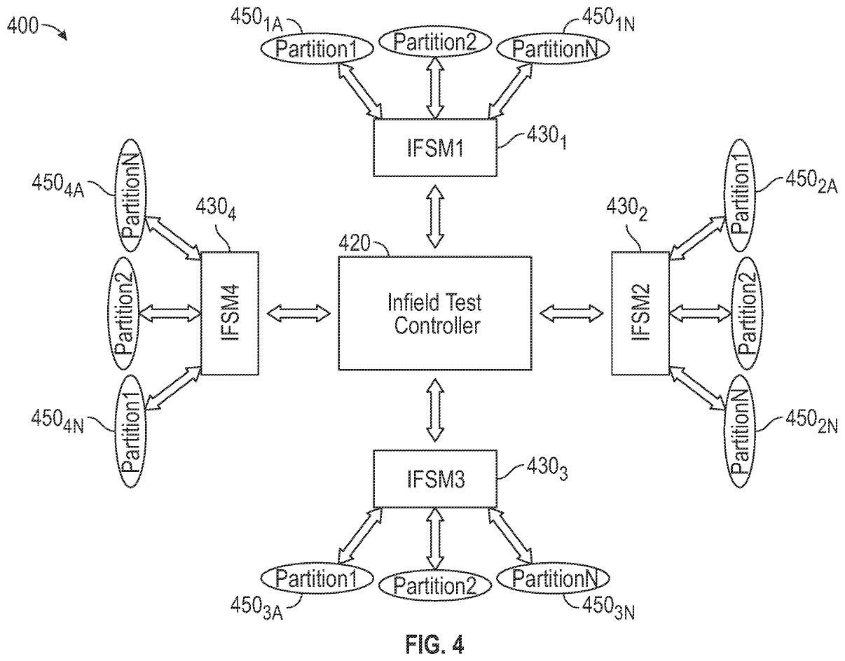

Referring now to FIG. 4, shown is a block diagram of a test arrangement in accordance with another embodiment. As shown in FIG. 4, test arrangement 400 is shown at a high level, including an infield test controller (IFTC) 420 and multiple infield sensor monitors (IFSMs) 430₁₋₄. Although four such infield sensor monitors are shown for ease of illustration, more or fewer may be present in a particular implementation.

As further shown, each sensor monitor 430 couples to multiple partitions 450_{1A-1N-4A-4N}. Each partition 450 includes test circuitry and multiple sensors as discussed above with regard to FIG. 2. And as shown, each partition 450 couples to corresponding sensor monitor 430 via a functional bus or a firmware accessible bus for monitoring of the sensors within the partitions, as well as providing test commands to present test circuitry. In turn, each sensor monitor 430 couples to infield test controller 420 via a trigger interface, details of which will be described further below.

Furthermore, understand that while in the illustration of FIG. 4, all of the circuitry shown may be implemented on a single semiconductor die, in other cases the different partitions represented may be present on multiple die. For example, one or more partition 450 (and sensor monitors 430) can be implemented on separate die, e.g., for a core die, a Universal Serial Bus (USB) controller, a Peripheral Component Interconnect Express (PCIe) controller, and a graphics controller, among others.

In operation of the FIG. 4 arrangement, based on threshold values programmed by firmware (not shown for ease of illustration) into IFSM 430 and based on real-time sensor values it read, IFSM 430 indicates to IFTC 420 regarding actions to be taken. In one example the actions that can be taken based on sensor values outside a safe range include determining to run only a few tests (e.g., scan chains) and informing a user (informing a user/original equipment manufacturer (OEM) enables early knowledge of an impending silicon issue). For example, based on an IFSM indication of unsafe sensor values (as compared to threshold values), IFTC 420 may determine to test only 50% of the scan chain circuitry.

In another example, IFTC 420 may determine to perform testing using low toggling patterns and informing the user. Again, letting a user know about running only low toggling patterns and not executing high toggling patterns provides an indication to the user/OEM about impending silicon issues.

IFSM 430 can also map critical sensor readings to the corresponding partition 450 (and the scan chain or other test circuitry there) based on real-time sensor readings. For example, as shown in Table 1 below, Sensor1 reading is not safe related to Partition 1, and that corresponds to scan chains 4-20. So, IFSM 430 asserts a trigger 1 signal high to IFTC 420. As a result, IFTC 420 tests all the scan chains except chains 4-20.

In embodiments, the same information can be sent to an OEM and/or user. As an example of Row 1 in Table 2 below, Sensor 1 (which may be a voltage droop monitor) in partition1 (core number 2 in CPU die number 2) is not safe and the corresponding scan chains (chains 4-20) are not tested as part of infield scan testing.

TABLE 1

| | | | | IFSM |
|---|---|---|---|---|
| Sensor | | | Scan chain | indication |
| Name | Criticality | Partition | numbering | to IFTC |
| Sensor 1 | Not Safe | Partition1 | Chain 4 to Chain 20 | Trigger |
| | | | (Disabled for testing) | 1 gets |
| | | | | asserted |
| Sensor 2 | Safe | Partition2 | Chain 30 to Chain 50 | Trigger |
| | | | (enabled for testing) | 2 gets |
| | | | | asserted |
| Sensor 3 | Not Safe | Partition4 | Chain 21 to Chain 29 | Trigger |
| | | | (disabled for testing) | 3 gets |
| | | | | asserted |
| Sensor 4 | Safe | Partition5 | Chain 51 to Chain 65 | Trigger |
| | | | (enabled for testing) | 4 gets |
| | | | | asserted |

TABLE 2

| | | | | IFSM |
|---|---|---|---|---|
| Sensor | | | Scan chain | indication |
| Name | Criticality | Partition | numbering | to IFTC |
| VDM | Not Safe | Core | Chain 4 to Chain 20 | Trigger |
| | | number 2 | (Disabled for | 1 gets |
| | | | testing) | asserted |
| Temperature | Safe | USB | Chain 30 to Chain 50 | Trigger |
| Sensor | | Controller | (enabled for | 2 gets |
| | | | testing) | asserted |
| Performance | Not Safe | IOSF bus | Chain 21 to Chain 29 | Trigger |
| counter | | | (disabled for | 3 gets |
| | | | testing) | asserted |
| IDV | Safe | Graphics | Chain 51 to Chain 65 | Trigger |
| | | controller | (enabled for | 4 gets |
| | | | testing) | asserted |

As discussed above, each IFSM 430 can send triggers to IFTC 420. IFTC 420 may be configured with priority logic. Then if trigger 1 from IFSM 430₁ and trigger 3 from IFSM 430₃ arrived in IFTC 420 at the same time, IFTC 420 may use an internal algorithm to decide on which trigger to purse first. Also, IFTC 420 can determine the priority among the multiple triggers from the same IFSM.

In other cases, adaptive infield testing can be performed in which dynamic adjustments to a testing schedule occur. As one example, this dynamic schedule adjustment may include scheduling the testing over multiple infield sessions or in the same infield session serially. In other words, if a particular sensor is not in the safe region (e.g., a particular sensor reading has overshot 20% above threshold), IFTC 420 can cause a given portion of the test circuitry to be disabled (e.g., 20% of the scan chains).

In another example, instead of disabling 20% of the scan chains completely, IFTC 420 can distribute these scan chains' testing over multiple infield periodic sessions or in the same periodic session window but not simultaneously.

In a first implementation, adaptive testing may be performed by distributing testing of test circuitry (e.g., scan chains) associated with unsafe sensor values across multiple infield periodic sessions.

With this implementation, the above operation in Table 2 now changes to that shown below in Tables 3A and 3B, which illustrate that testing of certain scan chains is adaptively performed in two different infield periodic session window 1 (Table 3A) and infield periodic session window 2 (Table 3B).

TABLE 3A

| | | | | IFSM |
|---|---|---|---|---|
| Sensor | | | | indication |
| Name | Criticality | Partition | Scan chain numbering | to IFTC |
| VDM | Safe | Core | Chain 4 to Chain 12 | Trigger |
| | | number 2 | (enabled for testing) | 1 gets |
| | | | instead of all chains | asserted |
| | | | from Chain 4 to Chain | |
| | | | 20 | |
| Temperature | Safe | USB | Chain 30 to Chain 50 | Trigger |
| Sensor | | Controller | (Enabled for testing) | 2 gets |
| | | | | asserted |
| Performance | Safe | IOSF bus | Chain 21 to Chain 25 | Trigger |
| counter | | | (Enabled for testing) | 3 gets |
| | | | instead of all chains | asserted |
| | | | from Chain 21 to | |
| | | | Chain 29 | |
| IDV | Safe | Graphics | Chain 51 to Chain 65 | Trigger |
| | | controller | (Enabled for testing) | 4 gets |
| | | | | asserted |

TABLE 3B

| | | | | IFSM |
|---|---|---|---|---|
| Sensor | | | Scan chain | indication |
| Name | Criticality | Partition | numbering | to IFTC |
| VDM | Safe | Core | Chain 13 to Chain 20 | Trigger |
| | | number 2 | (enabled for testing) | 1 gets |
| | | | | asserted |
| Temperature | Safe | USB | Chain 30 to Chain 50 | Trigger |
| Sensor | | Controller | (Enabled for testing) | 2 gets |
| | | | | asserted |
| Performance | Safe | IOSF bus | Chain 26 to Chain 29 | Trigger |
| counter | | | (enabled for testing) | 3 gets |
| | | | | asserted |
| IDV | Safe | Graphics | Chain 51 to Chain 65 | Trigger |
| | | controller | (Enabled for testing) | 4 gets |
| | | | | asserted |

In another implementation, adaptive testing can be performed by executing testing of test circuitry (e.g., scan chains) associated with unsafe sensor values one after the other in the same infield periodic session window, as shown in Table 4.

TABLE 4

| | | | | IFSM |
|---|---|---|---|---|
| Sensor | | | Scan chain | indication |
| Name | Criticality | Partition | numbering | to IFTC |
| VDM | Safe | Core | Chain 4 to Chain 12 | Trigger |
| | | number 2 | (enabled for testing) | 1 gets |
| | | | | asserted |
| VDM | Safe | Core | Chain 12 to Chain 20 | Trigger |
| | | number 2 | (enabled for testing) | 1 gets |
| | | | | asserted |
| Temperature | Safe | USB | Chain 30 to Chain 50 | Trigger |
| Sensor | | Controller | (Enabled for testing) | 2 gets |
| | | | | asserted |
| Performance | Safe | IOSF bus | Chain 21 to Chain 25 | Trigger |
| counter | | | (Enabled for testing) | 3 gets |
| | | | | asserted |
| Performance | Safe | IOSF bus | Chain 25 to Chain 29 | Trigger |
| counter | | | (Enabled for testing) | 3 gets |
| | | | | asserted |
| IDV | Safe | Graphics | Chain 51 to Chain 65 | Trigger |
| | | controller | (Enabled for testing) | 4 gets |
| | | | | asserted |

With the above-described techniques, an entity such as an OEM receives a notification that the infield tests are not executed or are otherwise modified and therefore OEM can immediately act on the SoC or on the corresponding SoC board. In this data center scenario, a given management entity can know about the silicon health through sensors before and after infield tests are executed.

With embodiments, various end users, OEMs and/or other entities may be advantaged with the information communicated herein. These communications regarding infield scan testing prevention, parameter monitoring and so forth can help OEMs or users of data centers, servers, automotive SoCs (or other users) to take appropriate actions. For example, when notified of potentially failing ICs (such as where infield scan testing is prevented from being performed or is otherwise modified), these entities can proactively take such ICs out of operation, potentially saving considerable business losses in case of data centers and servers, and even lives in case of automotive products. These actions can be taken well before a catastrophic event occurs and even before such event disrupts IC functionality.

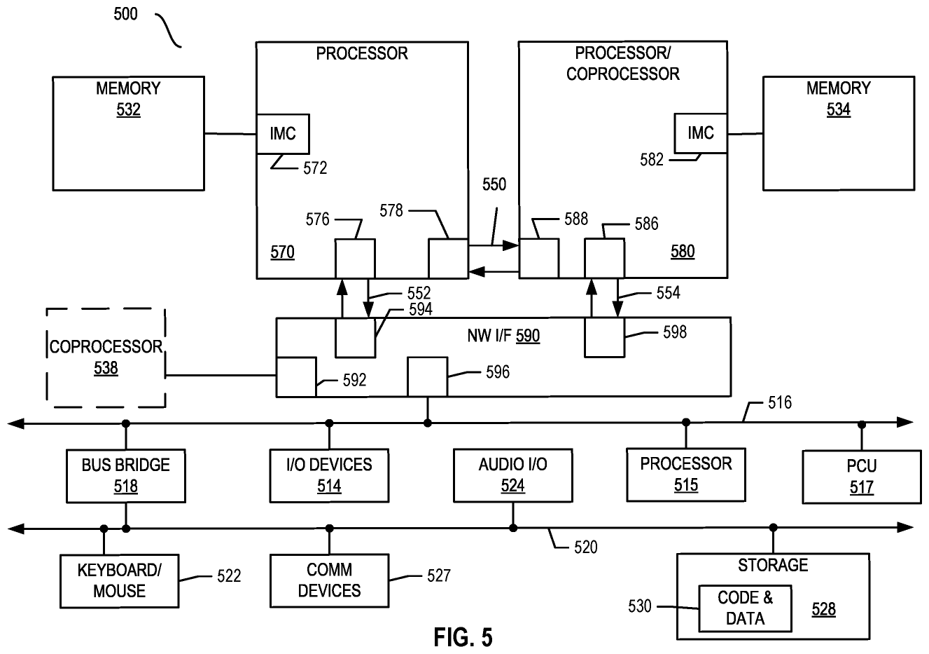

FIG. 5 illustrates an example computing system. Multiprocessor system 500 is an interfaced system and includes a plurality of processors or cores including a first processor 570 and a second processor 580 coupled via an interface 550 such as a point-to-point (P-P) interconnect, a fabric, and/or bus. In some examples, the first processor 570 and the second processor 580 are homogeneous. In some examples, first processor 570 and the second processor 580 are heterogenous. Though the example system 500 is shown to have two processors, the system may have three or more processors, or may be a single processor system. In some examples, the computing system is a SoC. In any event, system 500 includes test circuitry as described herein.

Processors 570 and 580 are shown including integrated memory controller (IMC) circuitry 572 and 582, respectively. Processor 570 also includes interface circuits 576 and 578; similarly, second processor 580 includes interface circuits 586 and 588. Processors 570, 580 may exchange information via the interface 550 using interface circuits 578, 588. IMCs 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect or another I/O interconnect. In some examples, first interface 516 is coupled to a power control unit (PCU) 517, which may include circuitry, software, and/or firmware to perform power management operations with regard to the processors 570, 580 and/or co-processor 538. PCU 517 provides control information to a voltage regulator (not shown) to cause the voltage regulator to generate the appropriate regulated voltage. PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other cases, PCU 517 may execute on a given one or more of cores (not shown) of processor 570 or 580. In some cases, PCU 517 may be implemented as a microcontroller (dedicated or general-purpose) or other control logic configured to execute its own dedicated power management code, sometimes referred to as P-code. In yet other examples, power management operations to be performed by PCU 517 may be implemented externally to a processor, such as by way of a separate power management integrated circuit (PMIC) or another component external to the processor. In yet other examples, power management operations to be performed by PCU 517 may be implemented within BIOS or other system software.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527 and storage circuitry 528. Storage circuitry 528 may be one or more non-transitory machine-readable storage media as described below, such as a disk drive or other mass storage device which may include instructions/code and data 530. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

### Example Core Architectures, Processors, and Computer Architectures.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

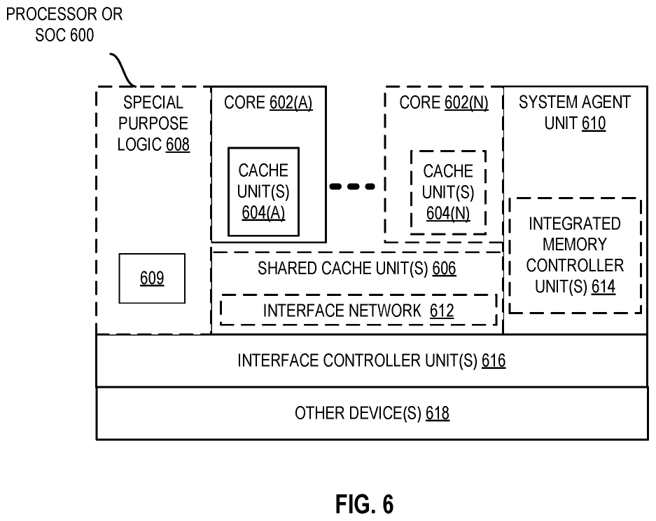

FIG. 6 illustrates a block diagram of an example processor and/or SoC 600 that may have one or more cores and an integrated memory controller. The solid lined boxes illustrate a processor 600 with a single core 602(A), system agent unit circuitry 610, and a set of one or more interface controller unit(s) circuitry 616, while the optional addition of the dashed lined boxes illustrates an alternative processor 600 with multiple cores 602(A)-(N), a set of one or more integrated memory controller unit(s) circuitry 614 in the system agent unit circuitry 610, and special purpose logic 608, as well as a set of one or more interface controller units circuitry 616. Note that the processor 600 may be one of the processors 570 or 580, or co-processor 538 or 515 of FIG. 5.

Thus, different implementations of the processor 600 may include: 1) a CPU with the special purpose logic 608 being integrated graphics and/or scientific (throughput) logic (which may include one or more cores, not shown), and the cores 602(A)-(N) being one or more general purpose cores (e.g., general purpose in-order cores, general purpose out-of-order cores, or a combination of the two); 2) a coprocessor with the cores 602(A)-(N) being a large number of special purpose cores intended primarily for graphics and/or scientific (throughput); and 3) a coprocessor with the cores 602(A)-(N) being a large number of general purpose in-order cores. Thus, the processor 600 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 600 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604(A)-(N) within the cores 602(A)-(N), a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602(A)-(N). In some examples, interface controller units circuitry 616 couple the cores 602 to one or more other devices 618 such as one or more I/O devices, storage, one or more communication devices (e.g., wireless networking, wired networking, etc.), etc.

In some examples, one or more of the cores 602(A)-(N) are capable of multi-threading. The system agent unit circuitry 610 includes those components coordinating and operating cores 602(A)-(N). The system agent unit circuitry 610 may include, for example, power control unit (PCU) circuitry and/or display unit circuitry (not shown). The PCU may be or may include logic and components needed for regulating the power state of the cores 602(A)-(N) and/or the special purpose logic 608 (e.g., integrated graphics logic). The display unit circuitry is for driving one or more externally connected displays. At least special-purpose logic 608 includes test circuitry 609, which may perform the adaptive infield testing based at least in part on silicon health information, as described herein. Of course, similar test circuitry may be located throughout processor 600, including within cores 602, system agent unit 610, and shared cache unit 606.

The cores 602(A)-(N) may be homogenous in terms of instruction set architecture (ISA). Alternatively, the cores 602(A)-(N) may be heterogeneous in terms of ISA; that is, a subset of the cores 602(A)-(N) may be capable of executing an ISA, while other cores may be capable of executing only a subset of that ISA or another ISA.

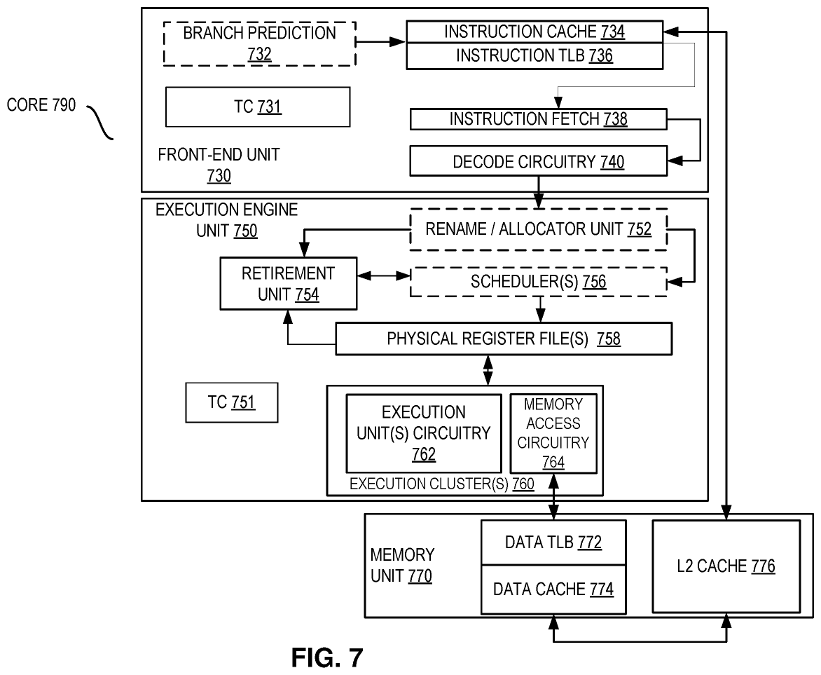

FIG. 7 shows a processor core 790 including front-end unit circuitry 730 coupled to execution engine unit circuitry 750, and both are coupled to memory unit circuitry 770. The core 790 may be a reduced instruction set architecture computing (RISC) core, a complex instruction set architecture computing (CISC) core, a very long instruction word (VLIW) core, or a hybrid or alternative core type. As yet another option, the core 790 may be a special-purpose core, such as, for example, a network or communication core, compression engine, coprocessor core, general purpose computing graphics processing unit (GPGPU) core, graphics core, or the like.

The front-end unit circuitry 730 may include branch prediction circuitry 732 coupled to instruction cache circuitry 734, which is coupled to an instruction translation lookaside buffer (TLB) 736, which is coupled to instruction fetch circuitry 738, which is coupled to decode circuitry 740. In one example, the instruction cache circuitry 734 is included in the memory unit circuitry 770 rather than the front-end circuitry 730. The decode circuitry 740 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 740 may further include address generation unit (AGU, not shown) circuitry. In one example, the AGU generates an LSU address using forwarded register ports, and may further perform branch forwarding (e.g., immediate offset branch forwarding, LR register branch forwarding, etc.). The decode circuitry 740 may be implemented using various different mechanisms. Examples of suitable mechanisms include, but are not limited to, look-up tables, hardware implementations, programmable logic arrays (PLAs), microcode read only memories (ROMs), etc. In one example, the core 790 includes a microcode ROM (not shown) or other medium that stores microcode for certain macroinstructions (e.g., in decode circuitry 740 or otherwise within the front-end circuitry 730). In one example, the decode circuitry 740 includes a micro-operation (micro-op) or operation cache (not shown) to hold/cache decoded operations, micro-tags, or micro-operations generated during the decode or other stages of the processor pipeline 700. The decode circuitry 740 may be coupled to rename/allocator unit circuitry 752 in the execution engine circuitry 750.

The execution engine circuitry 750 includes the rename/allocator unit circuitry 752 coupled to retirement unit circuitry 754 and a set of one or more scheduler(s) circuitry 756. The scheduler(s) circuitry 756 represents any number of different schedulers, including reservations stations, central instruction window, etc. In some examples, the scheduler(s) circuitry 756 can include arithmetic logic unit (ALU) scheduler/scheduling circuitry, ALU queues, address generation unit (AGU) scheduler/scheduling circuitry, AGU queues, etc. The scheduler(s) circuitry 756 is coupled to the physical register file(s) circuitry 758. Each of the physical register file(s) circuitry 758 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In one example, the physical register file(s) circuitry 758 includes vector registers unit circuitry, writemask registers unit circuitry, and scalar register unit circuitry. These register units may provide architectural vector registers, vector mask registers, general-purpose registers, etc. The physical register file(s) circuitry 758 is coupled to the retirement unit circuitry 754 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 754 and the physical register file(s) circuitry 758 are coupled to the execution cluster(s) 760. The execution cluster(s) 760 includes a set of one or more execution unit(s) circuitry 762 and a set of one or more memory access circuitry 764. The execution unit(s) circuitry 762 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). While some examples may include a number of execution units or execution unit circuitry dedicated to specific functions or sets of functions, other examples may include only one execution unit circuitry or multiple execution units/execution unit circuitry that all perform all functions. The scheduler(s) circuitry 756, physical register file(s) circuitry 758, and execution cluster(s) 760 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster—and in the case of a separate memory access pipeline, certain examples are implemented in which only the execution cluster of this pipeline has the memory access unit(s) circuitry 764). It should also be understood that where separate pipelines are used, one or more of these pipelines may be out-of-order issue/execution and the rest in-order.

In some examples, the execution engine unit circuitry 750 may perform load store unit (LSU) address/data pipelining to an Advanced Microcontroller Bus (AMB) interface (not shown), and address phase and writeback, data phase load, store, and branches.

The set of memory access circuitry 764 is coupled to the memory unit circuitry 770, which includes data TLB circuitry 772 coupled to data cache circuitry 774 coupled to level 2 (L2) cache circuitry 776. In one example, the memory access circuitry 764 may include load unit circuitry, store address unit circuitry, and store data unit circuitry, each of which is coupled to the data TLB circuitry 772 in the memory unit circuitry 770. The instruction cache circuitry 734 is further coupled to the level 2 (L2) cache circuitry 776 in the memory unit circuitry 770. In one example, the instruction cache 734 and the data cache 774 are combined into a single instruction and data cache (not shown) in L2 cache circuitry 776, level 3 (L3) cache circuitry (not shown), and/or main memory. The L2 cache circuitry 776 is coupled to one or more other levels of cache and eventually to a main memory.

As further shown in FIG. 7, various portions of the processor core 790 can include test circuitry configured to perform the adaptive infield testing based at least in part on silicon health information, as described herein. As seen, front-end unit 730 includes a test circuit 731, and execution engine 750 includes a test circuit 751. Although not shown for ease of illustration, understand that memory unit 770 also may include such test circuitry to monitor silicon health, and perform infield testing in a controlled manner based on the result of silicon health information.

The following examples pertain to further embodiments.

In one example, an apparatus includes: at least one functional circuit to execute operations, the at least one functional circuit adapted on at least one die; test circuitry to execute infield testing of at least a portion of the at least one functional circuit, the test circuitry adapted on the at least one die; a plurality of sensors to sense sensor information, the plurality of sensors adapted on the at least one die; and a test controller coupled to the test circuitry. The test controller is configured to prevent at least a portion of the test circuitry from execution of the infield testing based at least in part on the sensor information.

In an example, the apparatus further comprises a sensor monitor coupled to the plurality of sensors, wherein the sensor monitor is to compare a corresponding sensor value of the sensor information to a corresponding threshold value.

In an example, the sensor monitor is to identify a criticality violation based on comparison of a first sensor value of the sensor information to a first threshold value.

In an example, the sensor monitor is to inform the test controller regarding the criticality violation.

In an example, the test controller is to prevent at least the portion of the test circuitry from the execution of the infield testing in response to the criticality violation.

In an example, the plurality of sensors are coupled to the sensor monitor via a bus, at least one of the sensors comprising at least one register to store the sensor value.

In an example, firmware is to directly access the at least one of the sensors to obtain the sensor value from the at least one register.

In an example, the apparatus further comprises a bridge circuit coupled to the plurality of sensors, where firmware is to access at least some of the plurality of sensors via the bridge circuit.

In an example, the apparatus further comprises a plurality of partitions having at least some of the test circuitry and at least some of the plurality of sensors, each of the plurality of partitions comprising a sensor monitor to communicate the sensor information for the corresponding partition.

In an example, the test controller, in response to a criticality violation from a first partition of the plurality of partitions, is to prevent the first partition from the execution of the infield testing.

In an example, the test controller, in response to a criticality violation from a first partition of the plurality of partitions, is to cause the first partition to execute the infield testing serially on a first portion of the first partition and thereafter on a second portion of the first partition, and to cause generation of a notification regarding the serial infield testing.

In an example, the test controller is to cause generation of a notification regarding the prevention of at least the portion of the test circuitry from the execution of the infield testing.

In another example, a method comprises: receiving, in a test controller of a semiconductor die, from a plurality of sensors, sensor information; determining whether the sensor information is within a safe range; in response to determining that the sensor information is within the safe range, causing test circuitry of the semiconductor die to perform infield testing; and in response to determining that the sensor information is not within the safe range, preventing the test circuitry from performing at least a portion of the infield testing.

In an example, the method further comprises: reporting to a user that the sensor information is not within the safe range; and reporting to the user that at least the portion of the infield testing of the semiconductor die was prevented from being performed.

In an example, the method further comprises: comparing a first sensor value of the sensor information to a first threshold value; and determining that the sensor information is not within the safe range in response to the comparing.

In an example, the method further comprises in response to determining that the sensor information is not within the safe range: causing the test circuitry to perform the infield testing within a first portion of the semiconductor die; and preventing the test circuitry from performing the infield testing within a second portion of the semiconductor die, where the sensor information not within the safe range originates from the second portion of the semiconductor die.

In an example, the method further comprises in response to determining that the sensor information is not within the safe range: causing a first portion of the test circuitry to perform the infield testing within a first portion of the semiconductor die, the first portion of the test circuitry associated with the first portion of the semiconductor die, the sensor information not within the safe range originating from the first portion of the semiconductor die; and thereafter causing a second portion of the test circuitry to perform the infield testing within the first portion of the semiconductor die, the second portion of the test circuitry associated with the first portion of the semiconductor die.

In another example, a computer readable medium including instructions is to perform the method of any of the above examples.

In a further example, a computer readable medium including data is to be used by at least one machine to fabricate at least one integrated circuit to perform the method of any one of the above examples.

In a still further example, an apparatus comprises means for performing the method of any one of the above examples.

In yet another example, a system comprises: a first die comprising at least one core to execute operations, test circuitry to execute infield testing of the at least one core, a plurality of sensors to sense sensor information of the first die, and a test controller coupled to the test circuitry, the test controller, based on a trigger in response to a determination that at least a portion of the sensor information is not within a safe range, is to dynamically adjust an infield testing schedule and inform a user regarding the dynamic adjustment to the infield testing schedule; and a second die coupled to the first die, the second die comprising at least one functional circuit to execute operations, second test circuitry to execute infield testing of the at least one functional circuit, and a second plurality of sensors to sense sensor information of the second die. The second plurality of sensors are to provide the sensor information of the second die to the test controller.

In an example, the test controller is to dynamically adjust the infield testing schedule for serial infield testing comprising, to cause a first portion of the test circuitry to execute the infield testing and thereafter to cause a second portion of the test circuitry to execute the infield testing.

In an example, the test controller is to dynamically adjust the infield testing schedule comprising to prevent a portion of the test circuitry from execution of the infield testing, in response to a criticality violation from at least one sensor associated with the portion of the test circuitry.

Understand that various combinations of the above examples are possible.

Note that the terms “circuit” and “circuitry” are used interchangeably herein. As used herein, these terms and the term “logic” are used to refer to alone or in any combination, analog circuitry, digital circuitry, hard wired circuitry, programmable circuitry, processor circuitry, microcontroller circuitry, hardware logic circuitry, state machine circuitry and/or any other type of physical hardware component. Embodiments may be used in many different types of systems. For example, in one embodiment a communication device can be arranged to perform the various methods and techniques described herein. Of course, the scope of the present invention is not limited to a communication device, and instead other embodiments can be directed to other types of apparatus for processing instructions, or one or more machine readable media including instructions that in response to being executed on a computing device, cause the device to carry out one or more of the methods and techniques described herein.

Embodiments may be implemented in code and may be stored on a non-transitory storage medium having stored thereon instructions which can be used to program a system to perform the instructions. Embodiments also may be implemented in data and may be stored on a non-transitory storage medium, which if used by at least one machine, causes the at least one machine to fabricate at least one integrated circuit to perform one or more operations. Still further embodiments may be implemented in a computer readable storage medium including information that, when manufactured into a SOC or other processor, is to configure the SOC or other processor to perform one or more operations. The storage medium may include, but is not limited to, any type of disk including floppy disks, optical disks, solid state drives (SSDs), compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), magnetic or optical cards, or any other type of media suitable for storing electronic instructions.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
at least one functional circuit to execute operations, the at least one functional circuit adapted on at least one die;
test circuitry to execute infield testing of at least a portion of the at least one functional circuit, the test circuitry adapted on the at least one die;
a plurality of sensors to sense sensor information, the plurality of sensors adapted on the at least one die; and
a test controller coupled to the test circuitry, the test controller to prevent at least a portion of the test circuitry from execution of the infield testing based at least in part on the sensor information.

2. The apparatus of claim 1, further comprising a sensor monitor coupled to the plurality of sensors, wherein the sensor monitor is to compare a corresponding sensor value of the sensor information to a corresponding threshold value.

3. The apparatus of claim 2, wherein the sensor monitor is to identify a criticality violation based on comparison of a first sensor value of the sensor information to a first threshold value.

4. The apparatus of claim 3, wherein the sensor monitor is to inform the test controller regarding the criticality violation.

5. The apparatus of claim 4, wherein the test controller is to prevent at least the portion of the test circuitry from the execution of the infield testing in response to the criticality violation.

6. The apparatus of claim 2, wherein the plurality of sensors are coupled to the sensor monitor via a bus, at least one of the sensors comprising at least one register to store the sensor value.

7. The apparatus of claim 6, wherein firmware is to directly access the at least one of the sensors to obtain the sensor value from the at least one register.

8. The apparatus of claim 1, further comprising a bridge circuit coupled to the plurality of sensors, wherein firmware is to access at least some of the plurality of sensors via the bridge circuit.

9. The apparatus of claim 1, further comprising a plurality of partitions having at least some of the test circuitry and at least some of the plurality of sensors, each of the plurality of partitions comprising a sensor monitor to communicate the sensor information for the corresponding partition.

10. The apparatus of claim 9, wherein the test controller, in response to a criticality violation from a first partition of the plurality of partitions, is to prevent the first partition from the execution of the infield testing.

11. The apparatus of claim 9, wherein the test controller, in response to a criticality violation from a first partition of the plurality of partitions, is to cause the first partition to execute the infield testing serially on a first portion of the first partition and thereafter on a second portion of the first partition, and to cause generation of a notification regarding the serial infield testing.

12. The apparatus of claim 1, wherein the test controller is to cause generation of a notification regarding the prevention of at least the portion of the test circuitry from the execution of the infield testing.

13. At least one machine-readable storage medium comprising instructions that, when executed, cause a machine to perform a method comprising:
receiving, in a test controller of a semiconductor die, from a plurality of sensors, sensor information;
determining whether the sensor information is within a safe range;
in response to determining that the sensor information is within the safe range, causing test circuitry of the semiconductor die to perform infield testing; and
in response to determining that the sensor information is not within the safe range, preventing the test circuitry from performing at least a portion of the infield testing.

14. The at least one machine-readable storage medium of claim 13, wherein the method further comprises:
reporting to a user that the sensor information is not within the safe range; and
reporting to the user that at least the portion of the infield testing of the semiconductor die was prevented from being performed.

15. The at least one machine-readable storage medium of claim 14, wherein the method further comprises:
comparing a first sensor value of the sensor information to a first threshold value; and
determining that the sensor information is not within the safe range in response to the comparing.

16. The at least one machine-readable storage medium of claim 13, wherein the method further comprises in response to determining that the sensor information is not within the safe range:
causing the test circuitry to perform the infield testing within a first portion of the semiconductor die; and
preventing the test circuitry from performing the infield testing within a second portion of the semiconductor die, wherein the sensor information not within the safe range originates from the second portion of the semiconductor die.

17. The at least one machine-readable storage medium of claim 13, wherein the method further comprises in response to determining that the sensor information is not within the safe range:
causing a first portion of the test circuitry to perform the infield testing within a first portion of the semiconductor die, the first portion of the test circuitry associated with the first portion of the semiconductor die, the sensor information not within the safe range originating from the first portion of the semiconductor die; and
thereafter causing a second portion of the test circuitry to perform the infield testing within the first portion of the semiconductor die, the second portion of the test circuitry associated with the first portion of the semiconductor die.

18. A system comprising:
a first die comprising at least one core to execute operations, test circuitry to execute infield testing of the at least one core, a plurality of sensors to sense sensor information of the first die, and a test controller coupled to the test circuitry, the test controller, based on a trigger in response to a determination that at least a portion of the sensor information is not within a safe range, is to dynamically adjust an infield testing schedule and inform a user regarding the dynamic adjustment to the infield testing schedule; and
a second die coupled to the first die, the second die comprising at least one functional circuit to execute operations, second test circuitry to execute infield testing of the at least one functional circuit, and a second plurality of sensors to sense sensor information of the second die, wherein the second plurality of sensors are to provide the sensor information of the second die to the test controller.

19. The system of claim 18, wherein the test controller is to dynamically adjust the infield testing schedule for serial infield testing comprising, to cause a first portion of the test circuitry to execute the infield testing and thereafter to cause a second portion of the test circuitry to execute the infield testing.

20. The system of claim 18, wherein the test controller is to dynamically adjust the infield testing schedule comprising to prevent a portion of the test circuitry from execution of the infield testing, in response to a criticality violation from at least one sensor associated with the portion of the test circuitry.
